(19) United States
(12) Patent Application Publication
(10) Pub. No.: US 2025/0072166 A1
(43) Pub. Date: Feb. 27, 2025

(54) LIGHT-EMITTING DIODE AND LIGHT-EMITTING DEVICE

(71) Applicant: QUANZHOU SANAN SEMICONDUCTOR TECHNOLOGY CO., LTD., Quanzhou (CN)

(72) Inventors: Huihuang HUANG, Quanzhou (CN); Jin XU, Quanzhou (CN); Shuijie WANG, Quanzhou (CN); Weida ZHANG, Quanzhou (CN)

(21) Appl. No.: 18/809,392

(22) Filed: Aug. 20, 2024

(30) Foreign Application Priority Data
Aug. 21, 2023 (CN) 2023110514424

(51) Int. Cl. H01L 33/10

(52) U.S. Cl. CPC H01L 33/10

(57) ABSTRACT

A light-emitting diode includes a substrate, a semiconductor stack layer, a DBR stack structure that includes a first material layer and a second material layer, which are repeatedly stacked. Optical thicknesses of the first material layer and the second material layer are capable of: reflecting light within a first wavelength range and within a first angle range, transmitting a part of light within the first wavelength range and within a second angle range, where the first angle range is less than the second angle range. A reflectivity in response to light with at least one wavelength in a second wavelength range and having an incident angle of 0-10 degrees is ≥40%, the DBR stack structure has a color, and wavelengths contained in the second wavelength range are ≥ a critical wavelength of the color corresponding to the DBR stack structure through which AOI testing passes.

### CROSS-REFERENCE TO RELATED APPLICATION

This application claims priority to a Chinese patent application No. 202311051442.4, filed to China National Intellectual Property Administration (CNIPA) on Aug. 21, 2023, which is herein incorporated by reference in its entirety.

### TECHNICAL FIELD

The disclosure relates to the technical field of semiconductor devices, and more particularly to a light-emitting diode (LED) and a light-emitting device.

### BACKGROUND

LEDs have rapidly developed as light sources in the fields of lighting and display, especially in the field of backlighting displays. In recent years, the field of backlighting displays has put forward higher requirements for the display effect of display devices. As an improved version of a traditional LED, sub-millimeter LED (Mini LED) has been rapidly promoted, which can significantly improve the display effect of display devices.

The Mini LED needs to have a good light-emitting effect. There are two methods for improving the light-emitting effect of the Mini LED, one is a flip-chip design of the Mini LED, and the other is to control a light-emitting angle of the Mini LED. The size of the light-emitting angle of the Mini LED can directly determine the performance of various optical properties of the Mini LED. An existing solution is to implement the flip-chip design for the Mini LEDs, and to equip front and back surfaces of a Mini LED chip of the flip-chip structure with a distributed Bragg reflector (DBR) structure. The DBR layer is plated on the back surface of the Mini LED chip, which mainly enable the Mini LED chip to obliquely emit light at a large angle to improve overall uniformity of light-emitting length.

At present, package manufacturers commonly use an automated optical inspection (AOI) method to identify appearance information of chips and soldering conditions of soldering tin. However, when the Mini LED chip plated the DBR layer on its back surface is performed by subsequent AOI, some chips, with good soldering conditions of internal solder tins, may still fail AOI testing, resulting in a decrease in testing yield.

### SUMMARY

In view of the above disadvantages of the related art, an objective of the present disclosure is to provide a light-emitting diode (LED) and a light-emitting device, so as to avoid an influence of a distributed Bragg reflector (DBR) stack structure disposed on a back surface of the LED on an automated optical inspection (AOI) testing while improving a light-emitting angle of the LED.

In order to achieve the above objective and other related objectives, the present disclosure provides the LED as follows.

The LED includes: a substrate including a first surface and a second surface disposed opposite to the first surface; a semiconductor stack layer formed on the first surface of the substrate and configured to radiate light; and a DBR stack structure formed on the second surface of the substrate, which includes: a first material layer and a second material layer that are repeatedly stacked.

Optical thicknesses of the first material layer and the second material layer are capable of: reflecting light with any wavelength within a first wavelength range and having an incident angle within a first angle range, transmitting a part of light with any wavelength within the first wavelength range and having an incident angle within a second angle range, where the first angle range is less than the second angle range; and reflecting light with at least one wavelength within a second wavelength range and having an incident angle of 0-10 degrees) (°), where a reflectivity of the light with the at least one wavelength within the second wavelength range and having the incident angle of 0-10° is greater than or equal to 40%.

The DBR stack structure has a color, and wavelengths contained in the second wavelength range are greater than or equal to a critical wavelength of the color corresponding to the DBR stack structure that is capable of passing through an automated optical inspection (AOI).

According to another aspect of the present disclosure, the present disclosure further provides the light-emitting device, including: a packaging substrate; the above-described LED disposed on the packaging substrate; and an encapsulation layer disposed to cover the LED disposed on the packaging substrate.

Compared with the related art, the LED and the light-emitting device of the present disclosure have at least the following beneficial effects.

The LED of the present disclosure includes: the substrate, the semiconductor stack layer, and the DBR stack structure. The DBR stack structure includes the first material layer and the second material layer that are repeatedly stacked, and the optical thicknesses of the first material layer and the second material layer are capable of: reflecting the light with any wavelength within the first wavelength range and having the incident angle within the first angle range, transmitting the part of the light with any wavelength within the first wavelength range and having the incident angle within the second angle range, where the first angle range is less than the second angle range. The reflectivity of the light with the at least one wavelength within the second wavelength range and having the incident angle of 0-10° is greater than or equal to 40%. The DBR stack structure has the color, and the wavelengths contained in the second wavelength range are greater than or equal to the critical wavelength of the color corresponding to the DBR stack structure that is capable of passing through the AOI. Therefore, the LED of the present disclosure avoids the reflection of the wavelengths corresponding to the color of the DBR stack structure during the design of the DBR stack structure, so as to realize the reflections of small-angle light emissions and large-angle light emissions, while preventing the light leakage on the front surface of the Mini LED, transmitting the large-angle light emissions of the Mini LED to improve the brightness of the Mini LED and effectively improve the situation that the AOI testing fails.

The light-emitting device of the present disclosure includes the above-mentioned LED, which can also achieve the above effects.

### BRIEF DESCRIPTION OF DRAWINGS

FIG. 1 illustrates a schematic structural diagram of a light-emitting diode according to an embodiment of the present disclosure.

FIG. 2 illustrates a schematic structural diagram of a DBR stack structure according to an embodiment of the present disclosure.

FIG. 3 illustrates a schematic diagram of a geometric thickness setting of the DBR stack structure according to an embodiment of the present disclosure.

FIG. 4 illustrates a reflection spectrum of the DBR stack structure in response to light having different incident angles and radiated with a wavelength of 451 nanometers (nm) according to an embodiment of the present disclosure.

FIG. 5 illustrates a reflection spectrum of the DBR stack structure in response to light having an incident angle of 10° and radiated with different incident wavelengths according to an embodiment of the present disclosure.

FIG. 6 illustrates a reflection spectrum of multiple DBR stack structures in response to light having the incident angle of 10° according to an embodiment of the present disclosure.

FIG. 7 illustrates a reflection spectrum of the DBR stack structure in response to light having different incident angles according to an embodiment of the present disclosure.

FIG. 8 illustrates a schematic structural diagram of a light-emitting device according to an embodiment of the present disclosure.

### DESCRIPTION OF REFERENCE SIGNS ARE AS FOLLOWS

100 substrate;
200 semiconductor stack layer;
201 first semiconductor layer;
202 active layer;
203 second semiconductor layer;
204 first mesa;
205 second mesa;
301 first electrode;
302 second electrode;
400 insulated reflective layer;
501 first solder pad;
502 second solder pad;
600 DBR stack structure;
601 first material layer;
602 second material layer;
10 packaging substrate;
11 first bonding electrode;
12 second bonding electrode;
20 light-emitting diode;
30 encapsulation layer.

### DETAILED DESCRIPTION OF EMBODIMENTS

In order to improve light-emitting effect of the Mini LED, the Mini LED is set as a flip-chip structure, the Mini LED emits light from a side of a substrate, the substrate is further provided with a distributed Bragg reflector (DBR) layer, and the DBR layer has a larger reflection bandwidth. Therefore, the DBR layer has high reflectivity for small-angle light emissions and large-angle light emissions, which can greatly reflect the large-angle light emissions of the Mini LED while preventing light leakage on the front surface of the Mini LED that results in low brightness of the Mini LED. In view of this, it is necessary to design a DBR stack structure that has a relatively large reflectivity for the small-angle light emissions, has a relatively small reflectivity for the large-angle light emissions, and transmits the large-angle light emissions of the Mini LED while preventing the light leakage on the front surface of the Mini LED, so as to improve the brightness of the Mini LED. However, current packaging manufacturers commonly use the AOI testing method to identify the appearance information of the chip and the soldering condition of the soldering tin, and light sources of the AOI are generated by three LEDs of red, green, and blue, and then formed into different colors through the three primary colors. The product needs to pass through the AOI testing under the three light sources of red, green, and blue, and then enter the next process after all the inspections pass. When the Mini LED chip plated the DBR stack structure on the back surface thereof is performed by the subsequent AOI testing, the chip, with good soldering conditions of internal solder tins, may still fail the AOI testing, i.e., the AOI testing is not passed, resulting in a decrease in the testing yield.

In order to solve the above problems, the present embodiment provides a LED and a light-emitting device, so that the influence of the color of the DBR stack structure itself on subsequent AOI testing of the chip can be avoided while reflecting the small-angle light emissions and emitting the large-angle light emissions.

The LED in the present embodiment includes: a substrate including a first surface and a second surface disposed opposite to the first surface; a semiconductor stack layer formed on the first surface of the substrate and configured to radiate light; and a DBR stack structure formed on the second surface of the substrate and including a first material layer and a second material layer that are repeatedly stacked. Moreover, optical thicknesses of the first material layer and the second material layer are capable of: reflecting light with any wavelength within a first wavelength range and having an incident angle within a first angle range, transmitting a part of light with any wavelength within the first wavelength range and having an incident angle within a second angle range, and the first angle range is less than the second angle range.

Furthermore, the optical thicknesses of the first material layer and the second material layer are also capable of: reflecting light with at least one wavelength within a second wavelength range and having an incident angle of 0-10 degrees) (°, and a reflectivity of the light with the at least one wavelength within the second wavelength range is greater than or equal to 40%. In addition, the DBR stack structure has a color, and wavelengths contained in the second wavelength range are greater than or equal to a critical wavelength of the color corresponding to the DBR stack structure that is capable of passing through an automated optical inspection (AOI). Due to the fact that different DBR stack structures finally show different colors, the different colors can affect the optical reflection during the AOI testing. In the present embodiment, the wavelength range corresponding to the color of the DBR stack structure is determined as the second wavelength range, the reflectivity of the second wavelength range is controlled to reach more than 40%, and the AOI testing results can be improved.

In an illustrated embodiment, the first wavelength range is from 400 nanometers (nm) to 480 nm.

In an illustrated embodiment, when the color of the DBR stack structure is green, the second wavelength range is from 570 nm to 585 nm.

In an illustrated embodiment, the first material layer is a titanium oxide layer and the second material layer is a silicon oxide layer.

In an illustrated embodiment, the semiconductor stack layer includes: a first semiconductor layer, an active layer, and a second semiconductor layer that are sequentially stacked on the first surface of the substrate, a side of the semiconductor stack layer facing away from the first surface of the substrate includes a first mesa and a second mesa.

The first mesa is disposed to expose the second semiconductor layer of the semiconductor stack layer, and the first mesa is provided with a first electrode thereon.

The second mesa is disposed to expose the first semiconductor layer of the semiconductor stack layer, and the second mesa is provided with a second electrode thereon.

In an illustrated embodiment, the LED further includes: an insulated reflective layer, disposed to cover the first mesa and the second mesa of the semiconductor stacked layer, and to cover the first electrode and the second electrode.

In an illustrated embodiment, the LED further includes: a first solder pad, disposed on a position of the insulated reflective layer corresponding to the first electrode, penetrating through the insulated reflective layer, and electrically connected to the first electrode; and a second solder pad, disposed on a position of the insulated reflective layer corresponding to the second electrode, penetrating through the insulated reflective layer, and electrically connected to the second electrode.

The present embodiment further provides the light-emitting device, which includes: a packaging substrate; the LED as described above and disposed on the packaging substrate; and an encapsulation layer disposed to cover the LED disposed on the packaging substrate.

The present disclosure will be described in detail below with illustrated embodiments.

### Embodiment 1

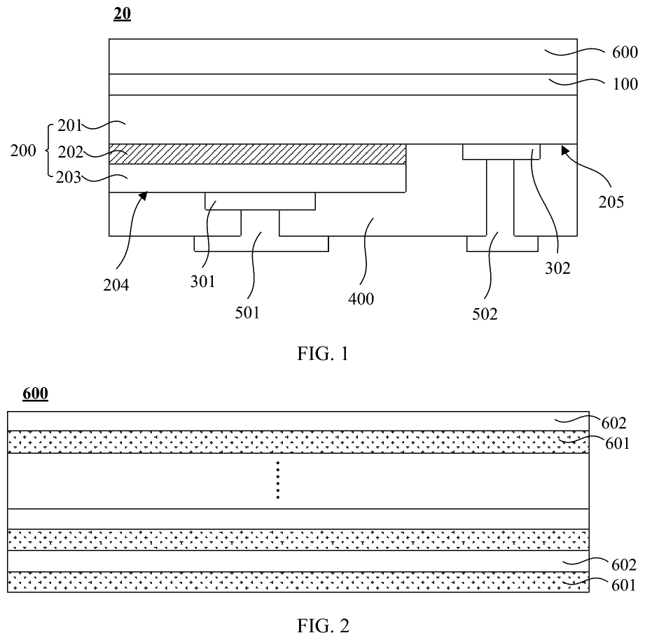

The present embodiment provides the LED. With reference to FIG. 1, the LED 20 includes a substrate 100, a semiconductor stack layer 200, and a DBR stack structure 600.

The substrate 100 is a transparent substrate 100, and the transparent substrate 100 can also be used as a growth substrate that is capable of growing a semiconductor light-emitting structure. Specifically, the substrate 100 can include a sapphire substrate, a silicon carbide substrate, a silicon substrate, a gallium nitride substrate, an aluminum nitride substrate, etc. The substrate 100 includes a first surface and a second surface disposed opposite to the first surface.

The semiconductor stack layer 200 is formed on the first surface of the substrate 100 and is used to radiate light. A wavelength range of the light radiated by the semiconductor stack layer 200 is preferably 420 nm to 480 nm, a peak wavelength thereof ranges from 440 nm to 455 nm, and the inverted LED 20 composed of the semiconductor stack layer 200 can be applied to a backlighting source of a liquid crystal display (LCD). The semiconductor stack layer 200 includes: a first semiconductor layer 201, an active layer 202, and a second semiconductor layer 203 that are sequentially stacked on the first surface of the substrate 100 in a direction perpendicular to the substrate 100. Specifically, the first semiconductor layer 201 can be an N-type semiconductor layer and the second semiconductor layer 203 can be a P-type semiconductor layer; of course, the first semiconductor layer 201 can be the P-type semiconductor layer and the second semiconductor layer 203 can be the N-type semiconductor layer. The first semiconductor layer 201 is configured to provide electrons for composite luminescence, and the second semiconductor layer 203 is configured to provide a hole for the composite luminescence. The active layer 202 is a single-quantum well or a multi-quantum well, is configured to perform the composite luminescence of the electrons and the hole, and can emit light with a wavelength ranging from 420 nm to 480 nm.

The semiconductor stack layer 200 includes a first mesa 204 and a second mesa 205. The first mesa 204 is disposed to expose the second semiconductor layer 203, and an exposed portion of the second semiconductor layer 203 is provided with a first electrode thereon. The second mesa 205 is disposed adjacent to the first mesa 204, the second mesa 205 is disposed to expose the first semiconductor layer 201, and an exposed portion of the first semiconductor layer 201 is provided with a second electrode 302 thereon. Specifically, the second mesa 205 can be formed by etching downward from the second semiconductor layer 203 to the first semiconductor layer 201. The first electrode 301 and the second electrode 302 are respectively formed on surfaces of the first mesa 204 and the second mesa 205 by sputtering or evaporation, and the first electrode 301 and the second electrode 302 are made of gold (Au) or an alloy of Au.

The LED 20 further includes an insulated reflective layer 400, the insulated reflective layer 400 is disposed to cover the first mesa 204 and the second mesa 205 of the semiconductor stack layer 200, and the insulated reflective layer 400 simultaneously exposes the first electrode 301 disposed on the first mesa 204 and the second electrode 302 disposed on the second mesa 205 of the semiconductor stack layer 200. In the present embodiment, the insulated reflective layer 400 is the DBR layer formed by alternately stacking materials with different refractive indexes. The DBR layer is made from at least two of the different materials selected from silicon dioxide (SiO₂), titanium dioxide (TiO₂), zinc peroxide (ZnO₂), zirconium dioxide (ZrO₂), and copper sesquioxide (Cu₂O₃). Specifically, the material with large refractive index and the material with low refractive index are alternately stacked, and the material with low refractive index is determined as SiO₂ and the material with large refractive index is determined as TiO₂.

The LED 20 further includes: a first solder pad 501 and a second solder pad 502, which are respectively formed on the insulated reflective layer 400 at positions corresponding to the first electrode 301 and the second electrode 302. Moreover, the first solder pad 501 is electrically connected to the first electrode 301 disposed on the first mesa 204; and the second solder pad 502 is electrically connected to the second electrode 302 disposed on the second mesa 205. In an illustrated embodiment, the first solder pad 501 and the second solder 502 are made of a metal material, which is specifically determined as any combination of Au, Ti, aluminium (Al), Cr, platinum (Pt), titanium tungsten (TiW) alloy, or nickel (Ni). In other embodiments, a transparent conductive layer or other current spreading layer may also be disposed between the first electrode 301 and the first mesa 204 or between the second mesa 205 and the second electrode 302, so as to play the role of ohmic contact and lateral current expansion.

The DBR stack structure 600 is disposed on the second surface of the substrate 100. However, the current packaging manufacturers commonly use the AOI testing method to identify the appearance information of the chip and the soldering condition of the soldering tin, and the light sources of the AOI are generated by three LEDs of red, green, and blue, and then formed into different colors through the three primary colors. The product needs to pass through the AOI testing under the three light sources of red, green, and blue, and then enter the next process after all the inspections pass. When the DBR stack structure 600 is plated on the back surface of the Mini LED chip and then the Mini LED chip is performed by the subsequent AOI testing, the chip, with good soldering conditions of internal solder tins, may still fail the AOI testing, i.e., the AOI testing is not passed, resulting in a decrease in the testing yield. Due to the fact that the back surface of the LED 20 needs to emit the large-angle light instead of totally reflecting the large-angle light emissions, the DBR stack structure 600 is also different according to different actual requirements, and different DBR stack structures 600 finally show different color effects, and this color effect can affect the optical reflection during AOI testing. Therefore, when designing the DBR system disposed on the back surface of the LED, it is not only necessary to consider the light type and brightness, but also the impact on subsequent AOI testing. If the color of the DBR stack structure disposed on the back surface of the LED is not suitable, even if the actual welding condition is good, the subsequent AOI testing will also be affected, resulting in that the subsequent AOI testing is not passed, which affects the AOI testing efficiency.

Based on the above problems, the design of the DBR stack structure 600 in the present embodiment comprehensively considers the above-mentioned problems, and with reference to FIG. 2, the DBR stack structure 600 includes a first material layer 601 and a second material layer 602, which are repeatedly stacked. Specifically, optical thicknesses of the first material layer 601 and the second material layer 602 are capable of: reflecting light with any wavelength within a first wavelength range and having an incident angle within a first angle range, transmitting a part of light with any wavelength within the first wavelength range and having an incident angle within a second angle range, where the first angle range is less than the second angle range; and reflecting light with at least one wavelength within a second wavelength range and having an incident angle of 0-10°, where a reflectivity of the light with the at least one wavelength in the second wavelength range is greater than or equal to 40%, so as to avoid the phenomenon that the AOI testing fails. Specifically, wavelengths contained in the second wavelength range are greater than or equal to a critical wavelength of the color corresponding to the DBR stack structure 600 through which the AOI testing can pass.

Specifically, the first wavelength range can be determined according to the wavelength of the light radiated by the semiconductor stack layer 200. For example, in the present embodiment, the first wavelength range is from 420 nm to 480 nm, which is the same as that of the semiconductor stack layer 200. The first angle range includes the small-angle light emissions, and the second angle range includes the large-angle light emissions. In the present embodiment, the first angle range is from 0° to 10°, and the second angle range is from 10° to 60°. The DBR stack structure 600 reflects the light emissions within the first angle range to prevent light leakage on the front side of the LED 20, and at the same time, reflects the light emissions within the second angle range, so that the light-emitting amount of the side surface of the LED 20 can be increased, thereby improving the light-emitting efficiency of the LED 20. Due to the total reflection phenomenon caused by the difference in the refractive indices between the materials of the substrate 100 and the DBR stack structure 600, the DBR stack structure 600 is difficult to regulate the transmittance of the light emissions exceeding 60°, and therefore, the second angle range is no more than 60°.

In the present embodiment, since the color displayed by the DBR stack structure 600 is close to green, the second wavelength range in the present embodiment ranges from 570 nm to 585 nm, and the reflectivity of the DBR stack structure 600 in the wavelength range is controlled to be at least 40% or above, which can improve the condition that the AOI testing is not passed.

Specifically, a reflectivity of the DBR stack structure 600 in response to the light with any wavelength within the first wavelength range and having the incident angle within the first angle range is greater than or equal to 95%; and a reflectivity of the DBR stack structure 600 in response to the part of light with any wavelength within the first wavelength range and having the incident angle within the second angle range is less than or equal to 60%, so as to realize the reflections of the small-angle light emissions and the partial transmission of the large-angle light emissions.

In an illustrated embodiment, a reflectivity of the DBR stack structure 600 in response to light within a wavelength range of 490 nm to 560 nm and having the incident angle within 0° to 10° is less than or equal to 25%. In an illustrated embodiment, a reflectivity of the DBR stack structure 600 in response to light within a wavelength range of 510 nm to 560 nm and having the incident angle within the first angle range is less than or equal to 25%. Therefore, the light leakage on the front surface of the flip-chip LED is prevented.

In an illustrated embodiment, the reflectivity of the DBR stack structure 600 in response to light within a wavelength range of 446 nm to 456 nm and having the incident angle within at least a part of the second angle range is less than or equal to 60%. Furthermore, the large-angle light-emitting ratio can be increased.

In order to make the LED 20 have the large reflectivity for the small-angle light emissions within a wavelength range from 420 nm to 480 nm as well as have the relatively large transmittance for the large-angle light emissions, and at the same time, have the reflectivity for the light within a wavelength range of 570 nm to 585 nm and having the incident angle of 0° to 10° of 40% or more, stacked thicknesses of the DBR stack structure 600 proposed in the present embodiment has the following characteristics.

The DBR stack structure 600 includes 10-20 pairs of layers, a number of which is an even number. Each pair of layers includes the first material layer 601 and the second material layer 602. The first material layer 601 has the large refractive index, and the second material layer 602 has the low refractive index. In addition, in at least the first pair of layers to the x-th pair of layers, the thickness of the first material layer 601 is less than 50 nm and the thickness of the second material layer 602 is between 50 nm and 100 nm; and the number of the x-th is half or more of the number of total pairs. In the remaining pairs of layers (excluding the last pair of layers), the thickness of the first material layer 601 is between 50 nm and 150 nm. Specifically, in an odd-numbered pair of layers, the thickness of the first material layer 601 is between 50 nm and 100 nm, and in an even-numbered pair of layers, the thickness of the second material layer 602 is between 100 nm and 150 nm. In the last pair of layers, the thickness of the first material layer 601 is between 100 nm and 150 nm, and the thickness of the second material layer 602 is between 250 nm and 300 nm.

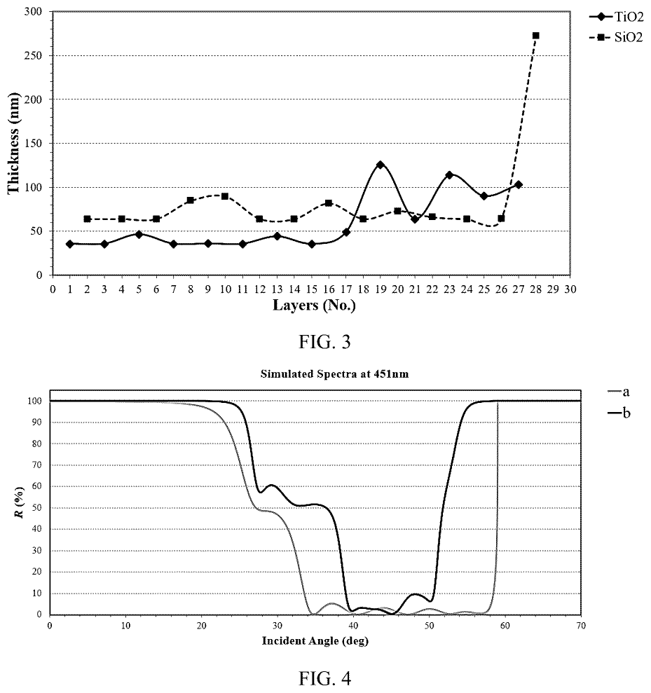

In an embodiment, the DBR stack structure 600 sequentially includes: a first pair of layers, a second pair of layers, and a third pair of layers, etc., and the fourteenth pair of layers on the second surface of the substrate 100. With reference to FIG. 3, from the first pair of layers to the eighth pair of layers, the thickness of the first material layer 601 ranges from 0 nm to 50 nm and the thickness of the second material layer 602 ranges from 50 nm to 100 nm; and from the ninth pair of layers to the fourteenth pair of layers, the thickness of the first material layer 601 ranges from 50 nm to 150 nm. Specially, the thickness of the first material layer 601 in the ninth pair of layers, the eleventh pair of layers, and the thirteenth pair of layers ranges from 50 nm to 100 nm, and the first material layer 601 in the tenth pair of layers and the twelfth pair of layers ranges from 100 nm to 150 nm, and the thickness of the second material layer 602 ranges from 50 nm to 100 nm. In the fourteenth pair of layers, the thickness of the first material layer 601 ranges from 100 nm to 150 nm and the thickness of the second material layer 602 ranges from 250 nm to 300 nm. Specifically, the total number of layers of the first material layer 601 and the second material layer 602 is 28, i.e., fourteen pairs of layers. Preferably, the first material layer 601 is a titanium oxide layer with a refractive index of 2.4-2.6, the geometric thickness of the first material layer 601 cannot be too thin, if the first material layer 601 is too thin, the membrane layer quality of the first material layer 601 is affected, the geometric thickness of the first material layer 601 cannot be too thick, and due to the light absorption phenomenon of the titanium oxide layer, the reflectivity of the DBR stack structure 600 can be reduced if the thickness of the first material layer 601 is too thick.

The second material layer 602 is preferably a silicon oxide layer with a refractive index of 1.4-1.5. In an illustrated embodiment of the present embodiment, FIG. 4 is a reflection spectrum of the DBR stack structure in response to light radiated with a wavelength of 451 nm according to the present embodiment of the disclosure. With reference to curve a shown FIG. 4, when the wavelength is 451 nm, the reflectivity of the DBR stack structure 600 corresponding to the light having the incident angle range of 0° to 25° is about 99%; the reflectivity thereof is between 60% and 99% corresponding to the light having the incident angle range of 25° to 28°; the reflectivity thereof is between 50% and 60% corresponding to the light having the incident angle range of about 28° to 35°; the reflectivity thereof is between 10% and 50% corresponding to the light having the incident angle range of about 35° to 39°; the reflectivity thereof is below 10% corresponding to the light having the incident angle range of about 39° to 51°; the reflectivity thereof is between 10% and 60% corresponding to the light having the incident angle range of about 51° to 53°; the reflectivity thereof is between 60% to 99% corresponding to the light having the incident angle range of about 53° to 56.5°; and the reflectivity thereof can reach 100% corresponding to the light having the incident angle greater than 60°.

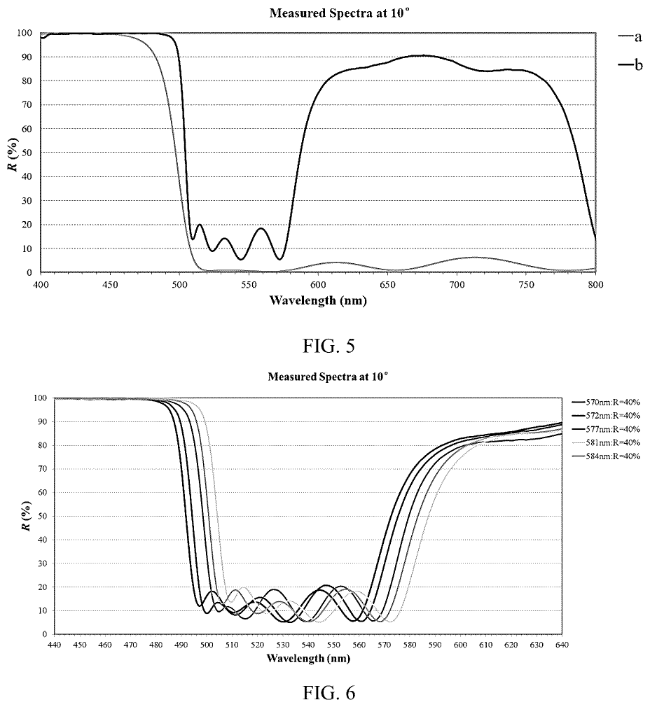

FIG. 5 a reflection spectrum of the DBR stack structure in response to light radiated within a wavelength range of 400 nm to 800 nm and having the incident angle of 10° according to the present embodiment of the present disclosure. With reference to a curve a shown in FIG. 5, when the incident angle is at 10°, the reflectivity of the DBR stack structure 600 in response to the light radiated at any wavelength within the wavelength range of 400 nm to 500 nm is greater than 95%; the reflectivity in response to the light radiated with at least some wavelengths within the wavelength range of 510 nm to 580 nm is less than or equal to 25%; and the reflectivity in response to the light radiated with at least some wavelengths within the wavelength range of 570 nm to 585 nm is between 25% and 40%. Moreover, the reflectivity in response to the light radiated at any wavelength within a wavelength range of 585 nm to 600 nm is between 40% and 80% and the reflectivity in response to the light radiated at any wavelength within the wavelength range of 600 nm to 760 nm is between 80% and 90%.

Curves b shown in FIG. 4 and FIG. 5 are reflection spectrums of the DBR stack structure 600 without considering the AOI testing. Although the LED 20 with the DBR stack structure 600 can transmit the large-angle light emissions and reflect the small-angle light emissions, when the AOI testing is performed thereon, it is easy to fail. Therefore, the curves b shown in FIG. 4 and FIG. 5 are used as comparisons in the reflection spectrums according to the present embodiment.

FIG. 6 is a reflection spectrum of multiple DBR stack structures in response to light radiated within a wavelength range of 440 nm to 640 nm and having the incident angle of 10° according to the present embodiment. With reference to FIG. 6, at the incident angle of 10°, multiple spectral curves therein have the reflectivity more than 40% in response to the light radiated within the second wavelength range (570 nm to 585 nm) according to the present embodiment. For example, when the light is radiated in the wavelength of 570 nm, the reflectivity of a rising starting position of the corresponding curve has reached 40%; or, when the light is radiated in the wavelength of 572 nm, the reflectivity of a rising starting position of the corresponding curve has reached 40%; or when the light is radiated in the wavelength of 577 nm, the reflectivity of a rising starting position of the corresponding curve has reached 40%; or, when the light is radiated in the wavelength of 581 nm, the reflectivity of a rising start position of the corresponding curve has reached 40%; or when the light is radiated in the wavelength of 584 nm, the reflectivity of a rising start position of the corresponding curve reaches 40%. It should be noted that each reflection spectrum in FIG. 6 can correspond to one DBR stack structure, and the LEDs corresponding to each DBR stack structure can be detected by subsequent AOI testing.

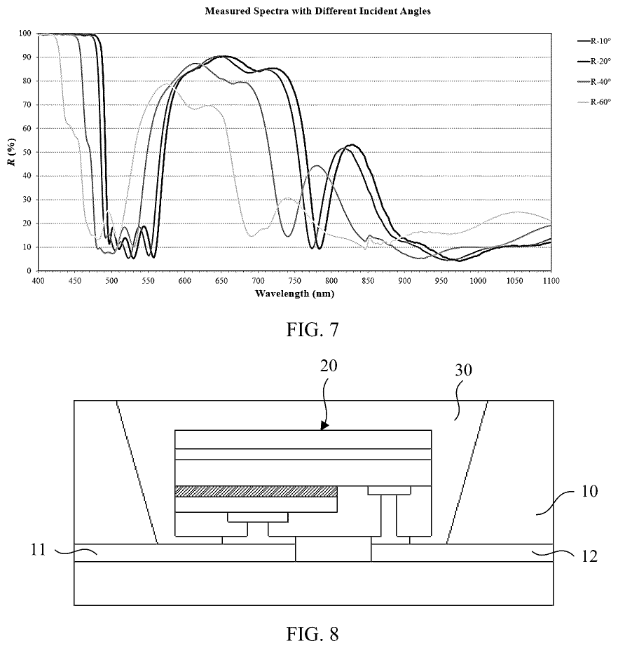

FIG. 7 is a reflection spectrum of the DBR stack structure in response to light radiated within a wavelength range of 400 nm to 1100 nm and having an incident angle of 10°, 20°, 40° and 60° respectively according to the present embodiment. With reference to FIG. 7, in response to the light radiated within the wavelength range of 400 nm to 480 nm, as the incident angle thereof increases, the reflectivity curve leads to the left, that is, as the incident angle increases, the reflectivity of the light radiated within the wavelength range of 400 nm to 480 nm is reduced by the DBR stack structure. Specifically, when the incident angle is 10° and 20° respectively, the reflectivity of the DBR stack structure in response to the light radiated within the wavelength range of 400 nm to 480 nm is greater than or equal to 95%. When the incident angle is 40°, the reflectivity of the DBR stack structure in response to the light radiated within a wavelength range of 446 nm to 456 nm is greater than or equal to 99%, the reflectivity in response to the light radiated within the wavelength range of 460 nm to 475 nm is greater than or equal to 40%, and the reflectivity in response to the light radiated within the wavelength range of 480 nm to 520 nm is less than or equal to 20%. Moreover, when the incident angle is 60°, the reflectivity in response to a part of the light radiated within the wavelength range of 446 nm to 456 nm is less than or equal to 60%, and the reflectivity in response to the light radiated within the wavelength range of 460 nm to 520 nm is less than 30%.

### Embodiment 2

The present embodiment provides a light-emitting device. With reference to FIG. 5, the light-emitting device includes a packaging substrate 10, the LED 20, and an encapsulation layer 30. The packaging substrate 10 is an insulating substrate, such as a packaging module substrate for a red-green-blue (RGB) display screen or a module substrate for backlighting display. Specifically, the packaging substrate 10 can preferably be planar, or it can include a reflective cup for surrounding the inverted LED 20, and the reflective cup defines a space for accommodating the inverted LED 20. Moreover, the packaging substrate 10 includes a first bonding electrode 11 and a second bonding electrode 12 that are electrically isolated with each other.

The LED 20 is the LED 20 described in the embodiment 1, which is not described again. A side of the LED 20 including the solder pads is fixed on the packaging substrate 10. Specifically, the first solder pad 501 disposed on the LED 20 is connected to the first bonding electrode 11 disposed on the packaging substrate 10, and the second solder pad 502 disposed on the LED 20 is connected to the second bonding electrode 12 disposed on the packaging substrate 10.

An encapsulation layer 30 is further included in the light-emitting device and is disposed to cover the LED 20 and a gap formed between the LED 20 and the packaging substrate 10. A refractive index of the encapsulation layer 30 is different from that of the DBR stack structure 600. The encapsulation layer 30 includes, but is not limited to, silica gel, and the refractive index of the silica gel is between 1.41 and 1.53.

The light-emitting device in the present embodiment includes the LED 200 described in the embodiment 1, and therefore can also reflect the small-angle light emissions. Therefore, the light-emitting device can transmit the large-angle light emissions of the Mini LED while preventing the light leakage on the front surface of the Mini LED, thereby to improve the brightness of the Mini LED and effectively improve the situation of the Mini LED that the AOI testing is not passed.

The above embodiments are merely illustrative of the principles and effects of the present disclosure, and are not intended to limit the present disclosure. Those skilled in the related art may modify or change the above embodiments without departing from the spirit and scope of the present disclosure. Therefore, all equivalent modifications or changes made by those skilled in the related art without departing from the spirit and technical ideas disclosed in the present disclosure shall still be covered by the claims of the present invention.

What is claimed is:

1. A light-emitting diode (LED), comprising:
a substrate, comprising a first surface and a second surface disposed opposite to the first surface;
a semiconductor stack layer, formed on the first surface of the substrate and configured to radiate light; and
a distributed Bragg reflector (DBR) stack structure, formed on the second surface of the substrate, wherein the DBR stack structure comprises: a first material layer and a second material layer, and the first material layer and the second material layer are repeatedly stacked;
wherein optical thicknesses of the first material layer and the second material layer are capable of:
reflecting light with any wavelength within a first wavelength range and having an incident angle within a first angle range, transmitting a part of light with any wavelength within the first wavelength range and having an incident angle within a second angle range, where the first angle range is less than the second angle range; and
reflecting light with at least one wavelength within a second wavelength range and having an incident angle of 0-10 degrees) (°), where a reflectivity of the light with the at least one wavelength within the second wavelength range and having the incident angle of 0-10° is greater than or equal to 40%; and
wherein the DBR stack structure has a color, and wavelengths contained in the second wavelength range are greater than or equal to a critical wavelength of the color corresponding to the DBR stack structure that is capable of passing through an automated optical inspection (AOI).

2. The LED according to claim 1, wherein the first wavelength range is from 400 nanometers (nm) to 480 nm.

3. The LED according to claim 2, wherein the first angle range is from 0° to 10°, and the second angle range is from 10° to 60°.

4. The LED according to claim 3, wherein a reflectivity of the DBR stack structure in response to the light with any wavelength within the first wavelength range and having the incident angle within the first angle range is greater than or equal to 95%; and
wherein a reflectivity of the DBR stack structure in response to the part of light with any wavelength within the first wavelength range and having the incident angle within the second angle range is less than or equal to 60%.

5. The LED according to claim 4, wherein a reflectivity of the DBR stack structure in response to light within a wavelength range of 490 nm to 560 nm and having the incident angle within the first angle range is less than or equal to 25%.

6. The LED according to claim 5, wherein a reflectivity of the DBR stack structure in response to light within a wavelength range of 510 nm to 560 nm and having the incident angle within the first angle range is less than or equal to 25%.

7. The LED according to claim 1, wherein when the color of the DBR stack structure is green, the second wavelength range is from 570 nm to 585 nm.

8. The LED according to claim 7, wherein a reflectivity of the DBR stack structure in response to the light with at least one wavelength in the second wavelength range and having the incident angle of 0-10° is greater than 40%.

9. The LED according to claim 4, wherein the reflectivity of the DBR stack structure in response to light within a wavelength range of 446 nm to 456 nm and having the incident angle within at least a part of the second angle range is less than or equal to 60%.

10. The LED according to claim 1, wherein a reflectivity of the DBR stack structure in response to light with any wavelength within a third wavelength range and having the incident angle of 0-10° is greater than 70%.

11. The LED according to claim 10, wherein the third wavelength range is from 600 nm to 750 nm.

12. The LED according to claim 1, wherein the first material layer is a titanium oxide layer and the second material layer is a silicon oxide layer.

13. The LED according to claim 1, wherein the semiconductor stack layer comprises: a first semiconductor layer, an active layer, and a second semiconductor layer sequentially stacked in that order on the first surface of the substrate, a side of the semiconductor stack layer facing away from the first surface of the substrate comprises a first mesa and a second mesa;
wherein the first mesa is disposed to expose the second semiconductor layer of the semiconductor stack layer, and the first mesa is provided with a first electrode thereon; and
wherein the second mesa is disposed to expose the first semiconductor layer of the semiconductor stack layer, and the second mesa is provided with a second electrode thereon.

14. The LED according to claim 13, further comprising:
an insulated reflective layer, disposed to cover the first mesa and the second mesa of the semiconductor stacked layer, and to cover the first electrode and the second electrode.

15. The LED according to claim 14, further comprising:
a first solder pad, disposed on a position of the insulated reflective layer corresponding to the first electrode, penetrating through the insulated reflective layer, and electrically connected to the first electrode; and
a second solder pad, disposed on a position of the insulated reflective layer corresponding to the second electrode, penetrating through the insulated reflective layer, and electrically connected to the second electrode.

16. A light-emitting device, comprising:
a packaging substrate;
the LED as claimed in claim 1, disposed on the packaging substrate; and
an encapsulation layer, disposed to cover the LED disposed on the packaging substrate.

17. The light-emitting device according to claim 16, further comprising: a first bonding electrode and a second bonding electrode; and
wherein the first bonding electrode and the second bonding electrode are electrically isolated from each other, and the first bonding electrode and the second bonding electrode are disposed on the packaging substrate.

18. The light-emitting device according to claim 16, wherein a refractive index of the encapsulation layer is less than a refractive index of the DBR stack structure.
